(19) United States
(12) Patent Application Publication
(10) Pub. No.: US 2024/0372021 A1
(43) Pub. Date: Nov. 7, 2024

(54) PHOTODIODE AND PHOTOSENSITIVE DEVICE

(71) Applicant: KYOCERA Corporation, Kyoto-shi, Tokyo (JP)

(72) Inventors: Naoyoshi KOMATSU, Tsukuba-shi (JP); Genshitaro KAWAMURA, Kirishima-shi (JP); Haruhiko UDONO, Hitachi-shi (JP)

(73) Assignee: KYOCERA Corporation, Kyoto-shi, Tokyo (JP)

(21) Appl. No.: 18/291,948

(22) PCT Filed: Jul. 27, 2022
(86) PCT No.: PCT/JP2022/028932

§ 371 Date: Jan. 25, 2024

(30) Foreign Application Priority Data
Jul. 29, 2021 (JP) 2021-124110

(51) Int. Cl. H01L 31/0336; H01L 31/0224; H01L 31/0352; H01L 31/0368; H01L 31/105

(52) U.S. Cl. CPC H01L 31/0336; H01L 31/022408; H01L 31/03529; H01L 31/03682; H01L 31/105; H01L 31/022475

(57) ABSTRACT

A photodiode includes a first insulator layer including a transparent electrode, a phosphorus-doped polysilicon layer in contact with the first insulator layer, an n-type magnesium silicide layer including a first surface in contact with an opposing surface of a surface of the phosphorus-doped polysilicon layer in contact with the first insulator layer, a p-type magnesium silicide layer including a second surface forming a p-n junction with an opposing surface of the first surface of the n-type magnesium silicide layer, and a second insulator layer including a metal electrode in contact with an opposing surface of the second surface of the p-type magnesium silicide layer. The metal electrode is made of a plurality of layers containing different kinds of metal.

### TECHNICAL FIELD

The present disclosure relates to a photodiode and a photosensitive device.

### BACKGROUND OF INVENTION

Photodiodes are known as elements that convert light into electrical signals. Patent Document 1 discloses a photodiode using Mg₂Si.

### CITATION LIST

### Patent Literature

Patent Document 1: WO 2019/187222

### SUMMARY

In one aspect, a photodiode includes a first insulator layer including a light incident portion, a phosphorus-doped polysilicon layer in contact with the first insulator layer, an n-type magnesium silicide layer including a first surface in contact with a surface opposed to a surface of the phosphorus-doped polysilicon layer in contact with the first insulator layer, a p-type magnesium silicide layer including a second surface forming a p-n junction with an opposing surface of the first surface of the n-type magnesium silicide layer, and a second insulator layer in contact with an opposing surface of the second surface of the p-type magnesium silicide layer and including a metal electrode, and the metal electrode is made of a plurality of layers containing different kinds of metal.

In one aspect, a photosensitive device includes the photodiode described above.

### BRIEF DESCRIPTION OF THE DRAWINGS

FIG. 1 is a schematic cross-sectional view for illustrating a photodiode according to a first embodiment.

FIG. 2 is a schematic view for illustrating an example of a transparent electrode.

FIG. 3 is a schematic cross-sectional view for illustrating a photodiode according to a second embodiment.

FIG. 4 is a schematic cross-sectional view for illustrating a photodiode according to a third embodiment.

### DESCRIPTION OF EMBODIMENTS

For a photodiode such as a technique described in Patent Document 1, various structures for suppressing a decrease in light reception sensitivity are desired.

Hereinafter, a photodiode and a photosensitive device according to embodiments will be described.

### First Embodiment

### Photodiode

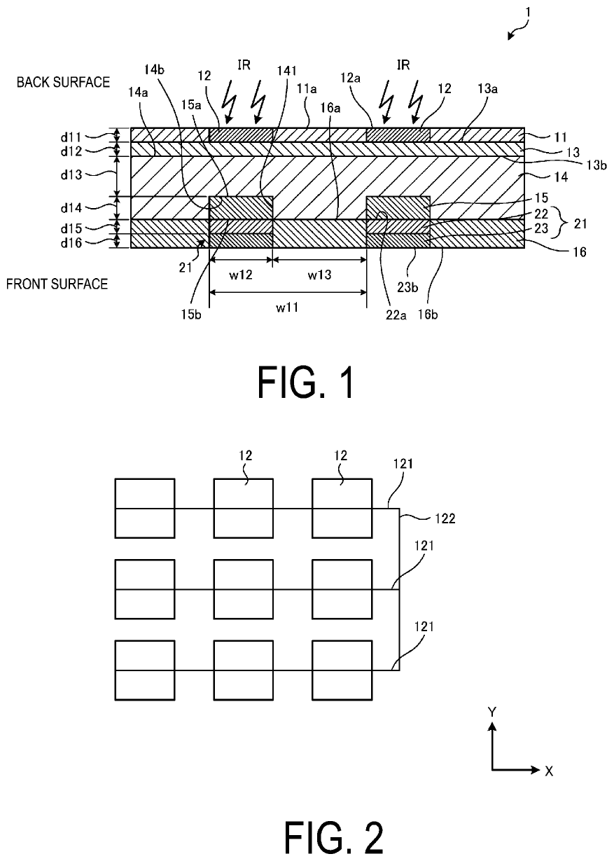

FIG. 1 is a schematic cross-sectional view for illustrating a photodiode according to a first embodiment. In FIG. 1, the lower side is a front surface, and the upper side is a back surface. A photodiode 1 is a PIN photodiode. The photodiode 1 uses Mg₂Si single crystal as a base material. The photodiode 1 receives infrared light (infrared rays) IR from the back surface side and reflects the infrared light IR. The photodiode 1 receives and reflects the infrared light IR from an n-type layer on the opposite side to a p-type layer.

The infrared light IR has a wavelength equal to or more than 0.8 μm and equal to or less than 3.0 μm.

As illustrated in FIG. 1, the photodiode 1 according to an embodiment includes a first insulator layer 11, a transparent electrode (light incident portion) 12, a phosphorus-doped polysilicon layer 13, an n-type magnesium silicide layer 14, a p-type magnesium silicide layer 15, a second insulator layer 16, and a metal electrode 21. A pixel width w11 that is a width for a pixel unit of the photodiode 1 is, for example, about 50 μm. In the present embodiment, the pixel width in a depth direction (not illustrated) is also the same as the pixel width w11.

The first insulator layer 11 is disposed on the back surface side. The first insulator layer 11 is made of SiO₂. A thickness d11 of the first insulator layer 11 is, for example, approximately 0.5 μm. The first insulator layer 11 includes the transparent electrode 12. The first insulator layer 11 includes a penetrating portion penetrating in a thickness direction. The transparent electrode 12 is disposed in the penetrating portion. The first insulator layer 11 is disposed to surround the periphery of the transparent electrode 12. A surface 11a of the first insulator layer 11 is exposed at the back surface of the photodiode 1.

The transparent electrode 12 is a light incident portion to the photodiode 1. The transparent electrode 12 is made of indium tin oxide (ITO). The transparent electrode 12 has a high transmittance in a visible light region and transmits infrared light. The transparent electrode 12 is formed such that light is incident on a p-n junction of the photodiode 1. The transparent electrode 12 is formed such that light is incident on a recessed portion 141 of an n-type magnesium silicide layer 14. The transparent electrode 12 has, for example, a rectangular shape in plan view. A surface 12a of the transparent electrode 12 is exposed at the back surface of the photodiode 1. One transparent electrode 12 is disposed for each of pixel units of the photodiode 1. A plurality of transparent electrodes 12 are disposed in the photodiode 1. A thickness d11 of the transparent electrode 12 is, for example, approximately 0.5 μm. The transparent electrode 12 has one side whose length w12 is, for example, about 30 μm. The transparent electrode 12 is disposed in alignment with positions of the p-type magnesium silicide layer 15 and the metal electrode 21.

FIG. 2 is a schematic view for illustrating an example of the transparent electrode. The transparent electrode 12 is disposed, for example, in a lattice shape in accordance with the arrangement of the pixel units of the photodiode 1. The transparent electrodes 12 adjacent in an X-axis direction are connected to each other by using a wiring line 121. The wiring lines 121 are connected to each other by using a wiring line 122. Since all the transparent electrodes 12 are connected in this manner, the transparent electrodes 12 are made equipotential. Each of materials of the wiring line 121 and the wiring line 122 is, for example, Cu or ITO, but is not limited thereto.

The phosphorus-doped polysilicon layer 13 is formed by doping Si with P. The phosphorus-doped polysilicon layer 13 is an n+-type semiconductor layer. The phosphorus-doped polysilicon layer 13 transmits infrared light. The phosphorus-doped polysilicon layer 13 is in contact with the first insulator layer 11 and the transparent electrode 12 on a surface opposite to an incident surface of the infrared light IR. In the phosphorus-doped polysilicon layer 13, a doping amount of P is controlled such that a P concentration is equal to or more than 10¹⁸ cm⁻³ and equal to or less than 10²⁰ cm⁻³. The phosphorus-doped polysilicon layer 13 has a thickness d13 of about 2 μm, for example.

The phosphorus-doped polysilicon layer 13 is interposed between the first insulator layer 11 and the transparent electrode 12, and the n-type magnesium silicide layer 14. This reduces a resistance between the transparent electrode 12 and the n-type magnesium silicide layer 14, reduces an attenuation of the infrared light IR, and improves light reception sensitivity.

The n-type magnesium silicide layer 14 includes a first surface 14a. The first surface 14a is in contact with an opposing surface 13b to the surface 13a in contact with the first insulator layer 11, of the phosphorus-doped polysilicon layer 13. The n-type magnesium silicide layer 14 transmits infrared light. The n-type magnesium silicide layer 14 is an n−-type semiconductor layer. The n-type magnesium silicide layer 14 is made of n-Mg₂Si. A doping amount of n− is controlled such that the n-type magnesium silicide layer 14 has a carrier concentration equal to or less than 5×10¹⁵ cm⁻³. A thickness d13 of the n-type magnesium silicide layer 14 is, for example, equal to or more than about 100 μm and equal to or less than about 500 μm. The thickness d13 of the n-type magnesium silicide layer 14 is a thickness of a portion where the recessed portion 141 is disposed.

The n-type magnesium silicide layer 14 includes a plurality of recessed portions 141 at predetermined intervals. The recessed portion 141 is formed on the front surface side of the n-type magnesium silicide layer 14. One recessed portion 141 is disposed for each pixel unit of the photodiode 1. The recessed portion 141 includes the p-type magnesium silicide layer 15. A p-n junction is formed at the recessed portion 141. The recessed portion 141 is disposed in alignment with positions of the transparent electrode 12, the p-type magnesium silicide layer 15, and the metal electrode 21.

The p-type magnesium silicide layer 15 is a p+-type semiconductor layer. The p-type magnesium silicide layer 15 is made of p+Mg₂Si. The p-type magnesium silicide layer 15 is disposed in the recessed portion 141. The p-type magnesium silicide layer 15 includes a second surface 15a. The second surface forms a p-n junction with an opposing surface 14b to the first surface 14a in the n-type magnesium silicide layer 14. The p-type magnesium silicide layer 15 has a thickness d14 of about 10 μm, for example. The p-type magnesium silicide layer 15 has a rectangular shape in plan view. The p-type magnesium silicide layer 15 includes one side whose length w12 is, for example, about 30 μm. An interval w13 between the p-type magnesium silicide layers 15 adjacent to each other is, for example, about 20 μm. The p-type magnesium silicide layer 15 is disposed in alignment with the positions of the transparent electrode 12 and the metal electrode 21.

The second insulator layer 16 is disposed on the front surface side. The second insulator layer 16 contains, for example, SiO2 or MgO. A thickness of the second insulator layer 16 is, for example, approximately 0.4 μm. The second insulator layer 16 includes the metal electrode 21. The second insulator layer 16 includes a penetrating portion penetrating in the thickness direction. The metal electrode 21 is disposed in the penetrating portion. The second insulator layer 16 is disposed to surround the periphery of the metal electrode 21. The second insulator layer 16 is in contact with the n-type magnesium silicide layer 14 on a surface thereof opposite to the incident surface of the infrared light IR. The second insulator layer 16 is in contact with an opposing surface 15b to the second surface 15a of the p-type magnesium silicide layer 15 at the metal electrode 21. The opposing surface 16b of the second insulator layer 16 is exposed on the front surface side of the photodiode 1.

The metal electrode 21 is in contact with the opposing surface 15b of the p-type magnesium silicide layer 15. The metal electrode 21 is disposed on the front surface side of the photodiode 1. The metal electrode 21 contains, for example, Ni and Au. The metal electrode 21 is layered on the p-type magnesium silicide layer 15. The metal electrode 21 has a rectangular shape in plan view. The metal electrode 21 includes one side whose length w12 is, for example, about 30 μm. An interval w13 between the metal electrodes 21 adjacent to each other is, for example, about 20 μm. A surface of the metal electrode 21 in contact with the opposing surface 15b of the p-type magnesium silicide layer 15 serves as a reflection surface of the infrared light IR. The metal electrode 21 is disposed in alignment with the positions of the transparent electrode 12 and the p-type magnesium silicide layer 15. The metal electrode 21 is constituted by a plurality of layers containing different kinds of metal. The metal electrode 21 includes, for example, a nickel electrode 22 and a gold electrode 23 in order from a layer in contact with the p-type magnesium silicide layer 15.

The nickel electrode 22 is in contact with the opposing surface 15b of the p-type magnesium silicide layer 15 on a reflection surface 22a thereof. The nickel electrode 22 has a rectangular shape in plan view. The nickel electrode 22 includes one side whose length w12 is, for example, about 30 μm. A thickness d15 of the nickel electrode 22 is, for example, approximately 0.2 μm.

The gold electrode 23 is in contact with the nickel electrode 22. The gold electrode 23 has a rectangular shape in plan view. The gold electrode 23 includes one side whose length w12 is, for example, about 30 μm. A thickness d16 of the gold electrode 23 is, for example, approximately 0.2 μm. A surface 23b of the gold electrode 23 is exposed on the front surface side of the photodiode 1.

A band pass filter (BPF) and an antireflection film are provided on the back surface side of the photodiode 1 configured as described above. An X-axis Cu wiring line and a Y-axis Cu wiring line are provided on the front surface side of the photodiode 1.

The infrared light IR is incident on the photodiode 1 from the n-type layer opposite to the p-type layer. The infrared light IR is incident on the back surface of the photodiode 1.

### Photosensitive Device

By disposing the photodiodes 1 configured as described above in an array, the photodiodes 1 can be used as a photosensitive device such as a photodetector or an imaging device.

### Actions

Reflection of the infrared light IR in the photodiode 1 will be described. The infrared light IR is incident from the back surface. The infrared light IR passes through the transparent electrode 12 and the phosphorus-doped polysilicon layer 13, and is incident from the first surface 14a of the n-type magnesium silicide layer 14. The infrared light IR incident from the first surface 14a passes through the n-type magnesium silicide layer 14 and the p-type magnesium silicide layer 15, and is reflected by the reflection surface 22a of the nickel electrode 22 included in the metal electrode 21. Return light of the infrared light IR reflected by the reflection surface 22a of the nickel electrode 22 included in the metal electrode 21 returns to the n-type magnesium silicide layer 14 side.

Since the photodiode 1 is a PIN photodiode, the n-type magnesium silicide layer 14 serving as an I layer is depleted. The infrared light IR is incident from the back surface, and thus, the infrared light IR reaches the n-type magnesium silicide layer 14 serving as the I layer without passing through the p-type magnesium silicide layer 15. The transparent electrode 12 and the phosphorus-doped polysilicon layer 13 transmit the infrared light IR. Thus, an optical path can be lengthened, and a photocurrent generated in the n-type magnesium silicide layer 14 is increased. Since the metal electrode 21 having low transmittance of infrared light, and the X-axis Cu wiring line and the Y-axis Cu wiring line that are for pixel selection are disposed on the front surface side that is the p-type magnesium silicide layer 15 side, the infrared light IR is not blocked before reaching the p-n junction.

### Effects

In the present embodiment, since the infrared light IR is incident from the back surface, the infrared light IR can reach the n-type magnesium silicide layer 14 serving as the I layer without passing through the p-type magnesium silicide layer 15 and the metal electrode 21. In the present embodiment, since the photodiode 1 is a PIN photodiode, the n-type magnesium silicide layer 14 serving as the I layer can be efficiently depleted. According to the present embodiment, a decrease in light reception sensitivity can be suppressed.

The present embodiment allows the p-n junction to be formed by providing the p-type magnesium silicide layer 15 in the recessed portion 141.

The present embodiment uses the transparent electrode 12 as the incident surface of the infrared light IR. The present embodiment allows the phosphorus-doped polysilicon layer 13 to be interposed between the transparent electrode 12 and the n-type magnesium silicide layer 14, thus reducing a resistance. The present embodiment interposes the phosphorus-doped polysilicon layer 13 to suppress an attenuation of the infrared light IR, allowing for improving light reception sensitivity.

In the present embodiment, the infrared light IR is incident from the transparent electrode 12 and reaches the p-n junction. The present embodiment allows the infrared light IR to reach the p-n junction of the n-type magnesium silicide layer 14 serving as the I layer without being absorbed or blocked before reaching the p-n junction. According to the present embodiment, a decrease in light reception sensitivity can be suppressed.

The present embodiment can dispose the metal electrode 21 and the X-axis Cu wiring line and the Y-axis Cu wiring line that are for pixel selection on the front surface side that is the p-type magnesium silicide layer 15 side. In the present embodiment, the infrared light IR is incident from the back surface, thus allowing the infrared light IR to reach the p-n junction of the n-type magnesium silicide layer 14 serving as the I layer without being absorbed or blocked before reaching the p-n junction. The present embodiment can reduce a decrease in light reception sensitivity due to wiring lines and a delay due to wiring lines.

The present embodiment improves pixel selectivity, thus allowing for improving frequency characteristics of the photodiode array.

On the other hand, when the infrared light IR is incident from the front surface as in the related art, the metal electrode 21 blocks an optical path of the infrared light IR. This reduces an amount of the infrared light IR reaching the p-n junction, which lowers the light reception sensitivity.

### Second Embodiment

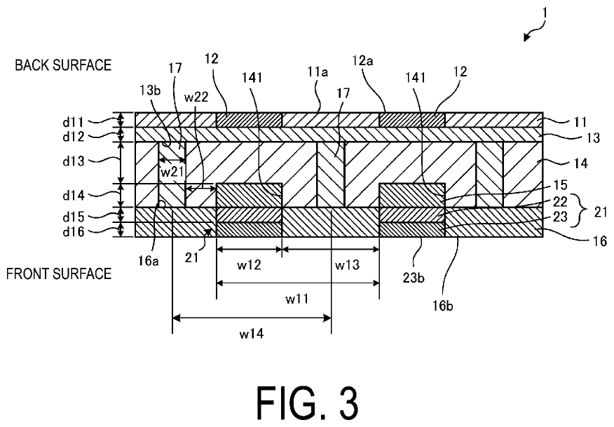

FIG. 3 is a schematic cross-sectional view for illustrating a photodiode according to a second embodiment. The photodiode 1 is different from the first embodiment in that a trench layer 17 is provided for each pixel unit. Portions in common with those in the first embodiment are denoted by the same reference signs, and descriptions thereof will be omitted. The following embodiments are also the same and/or similar.

The n-type magnesium silicide layer 14 includes the plurality of recessed portions 141 at predetermined intervals. The trench layer 17 penetrates the n-type magnesium silicide layer 14, and is in contact with the phosphorus-doped polysilicon layer 13 and the second insulator layer 16, at a portion of the n-type magnesium silicide layer 14 not including the recessed portion 141.

The trench layer 17 defines a pixel unit. The trench layer 17 serves as a potential barrier and suppresses interference of current signals between pixels. The trench layer 17 does not overlap the transparent electrode 12, the recessed portion 141, the p-type magnesium silicide layer 15, and the metal electrode 21 when viewed in a layering direction of each layer of the photodiode 1. The trench layer 17 is in contact with the surface 13b of the phosphorus-doped polysilicon layer 13 and a surface 16a of the second insulator layer 16. A width w21 of the trench layer 17 is, for example, approximately equal to or more than 0.5 μm and equal to or less than 20 μm. An interval w22 between the trench layer 17 and the p-type magnesium silicide layer 15 is, for example, equal to or less than 9.75 μm. An interval w14 between the trench layers 17 adjacent to each other is, for example, about 50 μm.

The trench layer 17 may form at least one selected from the group consisting of an n+-type of n-type magnesium silicide, an n+-type of phosphorus-doped polysilicon, SiO₂, MgO, and MgSiOx. The trench layer 17 may be an air layer.

When SiO₂ is formed in the trench layer 17, heat treatment at a temperature of about 900° C. is performed in a process after the trench formation. On the other hand, when an n+-type of n-type magnesium silicide and an n+-type phosphorus-doped polysilicon are formed in the trench layer 17, a process temperature after the trench formation becomes lower than the temperature described above. Thus, even when an interface using a different kind of substance is formed, an interface state density may be reduced. An effect of widening a range of material selection for regulating a diffusion current is obtained.

In the present embodiment, the trench layer 17 is formed in a portion of the n-type magnesium silicide layer 14 not including the recessed portion 141. In the present embodiment, the trench layer 17 is formed for each pixel unit. In the present embodiment, since the trench layer 17 partitions each pixel unit, isolation of a diffusion current, in particular among current signals, can be enhanced.

With such a configuration, when a photodiode array is formed, the trench layer 17 can reduce interference between pixels. In the present embodiment, a leakage current (dark current) is reduced as compared with the configuration without the trench layer 17. The present embodiment can reduce interference between pixels even when a pixel pitch is reduced.

### Third Embodiment

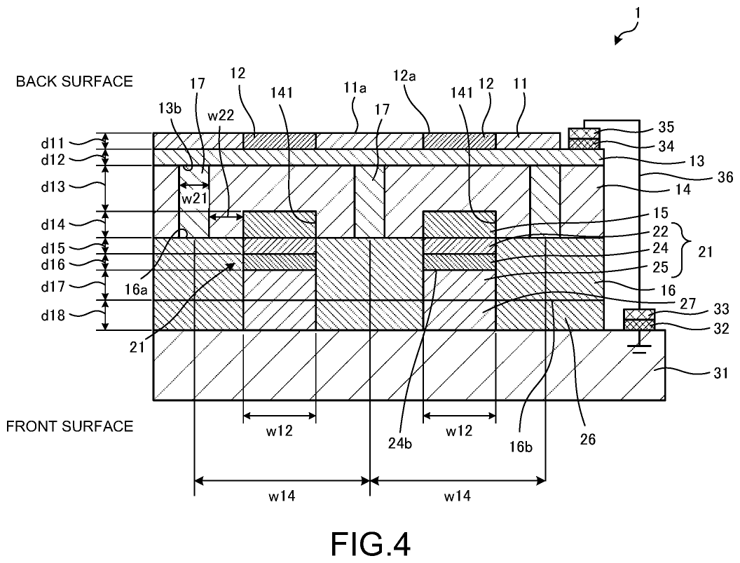

FIG. 4 is a schematic cross-sectional view for illustrating a photodiode according to a third embodiment. The photodiode 1 is different from the second embodiment in that an ROIC structure 31 to be connected to the metal electrode 21 is provided on the p-type magnesium silicide layer 15 side.

A nickel electrode 34 and a gold electrode 35 are provided on the surface 13a of the phosphorus-doped polysilicon layer 13 in order from the layer in contact with the phosphorus-doped polysilicon layer 13.

The metal electrode 21 includes, for example, the nickel electrode 22 configured in a manner similar to that in the first embodiment, a titanium electrode 24, and a copper electrode 25 in order from the layer in contact with the p-type magnesium silicide layer 15. The copper electrode 25 of the metal electrode 21 is Cu—Cu bonded to copper of a bonding electrode 27 of the ROIC structure 31.

The titanium electrode 24 is layered with the nickel electrode 22 and the copper electrode 25. The titanium electrode 24 has a rectangular shape in plan view. The titanium electrode 24 includes one side whose length w12 is, for example, about 30 μm. A thickness d16 of the titanium electrode 24 is, for example, approximately 0.2 μm.

The copper electrode 25 is in contact with the titanium electrode 24. The copper electrode 25 has a rectangular shape in plan view. The copper electrode 25 includes one side whose length w12 is, for example, about 30 μm. A thickness d17 of the copper electrode 25 is, for example, approximately equal to or less than 10 μm. The copper electrode 25 is connected to the readout IC (ROIC) structure 31 by Cu—Cu bonding through the bonding electrode 27 containing copper on the front surface side of the photodiode 1.

The ROIC structure 31 is a circuit that extracts a current of the photodiode 1. The ROIC structure 31 is disposed on the front surface side of the photodiode 1. The ROIC structure 31 uses Si as a base material. The ROIC structure 31 is, for example, a voltage follower, a metal oxide semiconductor field effect transistor (MOSFET), or a MOS capacitor. The ROIC structure 31 is provided with a nickel electrode 32 and a gold electrode 33.

The ROIC structure 31 includes a third insulator layer 26 that is in contact with the opposing surface 16b of the surface 16a of the second insulator layer 16 in contact with the n-type magnesium silicide layer 14 and includes the bonding electrode 27 containing copper.

The third insulator layer 26 is provided between the second insulator layer 16 and the ROIC structure 31. The third insulator layer 26 is disposed on the front surface side. The third insulator layer 26 is made of SiO₂. A thickness d18 of the third insulator layer 26 is, for example, approximately equal to or less than 10 μm. The third insulator layer 26 includes the bonding electrode 27. The third insulator layer 26 includes a penetrating portion penetrating in a thickness direction. The bonding electrode 27 is disposed in the penetrating portion. The third insulator layer 26 is disposed to surround the periphery of the bonding electrode 27.

The bonding electrode 27 has, for example, a rectangular shape in plan view. One bonding electrode 27 is disposed for each pixel unit of the photodiode 1. The plurality of bonding electrodes 27 are disposed in the photodiode 1. A thickness d18 of the bonding electrode 27 is, for example, approximately equal to or less than 10 μm. The bonding electrode 27 includes one side whose length w12 is, for example, about 30 μm. The bonding electrode 27 is disposed in alignment with a position of the metal electrode 21. The bonding electrode 27 is in contact with the ROIC structure 31. The bonding electrode 27 is Cu—Cu bonded to the copper electrode 25.

The nickel electrode 32 and the gold electrode 33 are connected through an electric wire 36 to the nickel electrode 34 and the gold electrode 35 that are provided on the surface 13a of the phosphorus-doped polysilicon layer 13.

The present embodiment bonds the pixels of the ROIC structure 31 and the photodiode array by Cu—Cu bonding. The present embodiment can transmit a generated current generated at the p-n interface through the electrode. According to the present embodiment, wiring delay can be suppressed. This allows the present embodiment to perform high-speed reading.

The embodiments disclosed in the present application can be modified without departing from the spirit and scope of the invention. The embodiments and variations thereof disclosed in the present application can be combined as appropriate.

Characteristic embodiments have been described in order to fully and clearly disclose the technique according to the appended claims. However, the appended claims are not to be limited to the embodiments described above and may be configured to embody all variations and alternative configurations that those skilled in the art may make within the underlying matter set forth herein.

In the above description, Cu—Cu bonding is used, but the present invention is not limited thereto. For example, the pixel portion and the ROIC structure 31 may be connected by using an In bump, performing Au—Au bonding, or the like. When the Au—Au bonding is performed, the electrode of the metal electrode 21 and the bonding electrode of the ROIC structure 31 contain gold. High-speed reading is also possible when bonding is performed by using the In bump, performing Au—Au bonding, or the like.

### REFERENCE SIGNS

1 Photodiode
11 First insulator layer
12 Transparent electrode (light incident portion)
13 Phosphorus-doped polysilicon layer
13a Surface
13b Surface
14 n-type magnesium silicide layer
14a First surface
14b Opposing surface
141 Recessed portion
15 p-type magnesium silicide layer
15a Second surface
15b Opposing surface
16 Second insulator layer
16a Surface
16b Opposing surface
21 Metal electrode
22 Nickel electrode
23 Gold electrode

1. A photodiode, comprising:
a first insulator layer comprising a light incident portion;
a phosphorus-doped polysilicon layer in contact with the first insulator layer;
an n-type magnesium silicide layer comprising a first surface in contact with a surface opposed to a surface of the phosphorus-doped polysilicon layer in contact with the first insulator layer;
a p-type magnesium silicide layer comprising a second surface comprising a p-n junction with an opposing surface of the first surface of the n-type magnesium silicide layer; and
a second insulator layer in contact with an opposing surface of the second surface of the p-type magnesium silicide layer and comprising a metal electrode,
wherein the metal electrode comprises a plurality of layers containing different kinds of metal.

2. The photodiode according to claim 1,
wherein the n-type magnesium silicide layer comprises a recessed portion, and
the recessed portion comprises a p-type magnesium silicide layer.

3. The photodiode according to claim 2,
wherein light is incident on the recessed portion.

4. The photodiode according to claim 1,
wherein the n-type magnesium silicide layer comprises n-Mg₂Si, and
the p-type magnesium silicide layer comprises p+Mg₂Si.

5. The photodiode according to claim 1,
wherein the metal electrode comprises nickel located on the p-type magnesium silicide layer and gold located on the nickel.

6. The photodiode according to claim 2,
wherein the n-type magnesium silicide layer comprises a plurality of the recessed portions at predetermined intervals and
comprises a trench layer penetrating the n-type magnesium silicide layer at a portion not comprising the plurality of the recessed portions and in contact with the phosphorus-doped polysilicon layer and the second insulator layer.

7. The photodiode according to claim 6,
wherein the trench layer comprises at least one selected from the group consisting of n+Mg₂Si, phosphorus-doped polysilicon, SiO₂, MgO, MgSiOx, and an air layer.

8. The photodiode according to claim 6, further comprising
an ROIC structure connected to the metal electrode on a side of the p-type magnesium silicide layer.

9. The photodiode according to claim 8,
wherein the ROIC structure comprises a third insulator layer in contact with an opposing surface of a surface of the second insulator layer in contact with the n-type magnesium silicide layer and comprising a bonding electrode containing copper or gold,
the metal electrode comprises nickel located on the p-type magnesium silicide layer, titanium located on the nickel, and copper or gold located on the titanium, and
the copper or the gold of the metal electrode and the copper or the gold of the bonding electrode of the ROIC structure are bonded by Cu—Cu bonding or Au—Au bonding.

10. A photosensitive device, comprising
a photodiode described in any claim 1.
